(19) United States
(12) Patent Application Publication
(10) Pub. No.: US 2005/0076276 A1
(43) Pub. Date: Apr. 7, 2005

(54) System and method for defect projection in transaction management in a target computer environment

(75) Inventors: Theodore F. Rivera, Raleigh, NC (US); Adam Tate, Raleigh, NC (US); Scott A. Will, Wake Forest, NC (US)

Correspondence Address: Gerald R. Woods;IBM Corporation T81/503, PO Box 12195, Research Triangle Park, NC, 27709, US

(73) Assignee: International Business Machines Corporation, Armonk, NY (US)

(21) Appl. No.: 10/680,039

(22) Filed: Oct. 7, 2003

(51) Int. Cl. G01R 31/28

(52) U.S. Cl. 714/724

(57) ABSTRACT

A system and method for assessing the probability of success of business transactions by a software application that will interact with one or more other software applications in a target computer environment. Known defect data is gathered for each software application that constitutes a portion of the business transaction as it runs in the target environment, analyzed in view of the other software applications and the target computer environment, and then a transaction failure rate is predicted for the business transaction operating within the computer environment.

### BACKGROUND OF THE INVENTION

1. Field of the Invention

The present invention generally relates to computer software and quality control. More particularly, the invention relates to an automated system for predicting the failure rate of a business transaction using a number of software programs operating in a target computer environment.

2. Description of the Related Art

Customers that purchase software desire an effective means to gauge the reliability and overall quality of the software, especially when the software is to be placed in an operating computer environment. In a commercial software environment, the expectation of the quality of software is even greater due to the increasing pressures on organizations to justify cost and demonstrate return on investment for their software acquisitions. At the same time, software solutions are becoming increasingly complex with individual applications having a rising number of dependencies on other applications that often provide a wide range of functions and services. And a poor software purchase can severely affect the business, from harming productivity to fully stopping a computer-dependent business upon a software failure.

Often, the focus on software quality is limited to the consideration of an individual software package. At best, thorough integration testing of individual software applications takes place as this testing takes place in a simulated environment where other applications are also present. Purchase of a software application that requires true transaction management presents additional problems in that not only does the new software require the use of multiple different applications in an integrated computer environment (often from multiple vendors), but the software packages being used must also take into account sequencing and paths for transaction flow. Such analysis is more complicated than more simple integration issues that occur with software, such as coexistence and dependency. Methods at present do not exist that adequately allow clients to gauge or quantify how effectively their overall solution will perform for true business transaction management. Neither can software vendors effectively assess the risks of failure for their solutions that are aimed at such business transactions.

Accordingly, it would be advantageous to provide an effective, measurable system and method to predict the business transaction failure or success rate, as opposed to merely considering the probabilities of success or failure of software applications in isolation from their business context. The system and method should provide predictive information for the performance of such transactions in the target client environment with data that can be used to quantify client risk, and can thereby provide data for return on investment and cost of ownership considerations in software acquisition decisions that relate to business transactions. Further, the system and method should be able to address the stability of business transactions in the target computer environment as opposed to individual software applications considered in isolation. It is thus to the provision of such a system and method of providing an automated computer tool and methodology to predict the transaction failure rate of a software program operating in a target computer environment to that the present invention is primarily directed.

### SUMMARY OF THE INVENTION

The present invention is a system and method for assessing the probability of business transaction success in a target computer environment. The system gathers defect data for the all software applications used to complete a given business transaction, analyzes the defect data across these software applications, and predicts a business transaction failure rate within the computer environment.

The method for assessing the probability of a business transaction success includes the steps of gathering known defect data for the each software application on which the business transaction depends, analyzing the defect data in the target computer environment, and then predicting a transaction failure rate for the business transaction operating within the computer environment.

It is therefore an object of the system and method to provide an effective, measurable method to predict the business transaction failure or success rate for a given business transaction as it functions in a target environment to increase confidence in the value of complex software solution purchases. The system and method will provide predictive information for the performance of individual business transactions in the target computer environment, and can provide data to quantify client risk, return on investment and cost of ownership considerations in software acquisition decisions that specifically relate to these business transactions. The system and method thereby also address the stability of business transactions through the target computer environment, as opposed to the likely success or failure of individual applications.

Other objects, advantages, and features of the present invention will become apparent after review of the hereinafter set forth Brief Description of the Drawings, Detailed Description of the Invention, and the claims.

### BRIEF DESCRIPTION OF THE DRAWINGS

FIG. 1 is a block diagram of a computer platform executing the logic to practice the present invention.

FIG. 2 is a flowchart illustrating the process executed on the system to predict a business transaction failure rate for a particular business transaction operating in a target computer environment.

### DETAILED DESCRIPTION OF THE INVENTION

Many software manufacturers and vendors do not use the available data to perform any kind of predictive analysis for individual software applications, much less analysis specific to business transactions as they function across a target computer environment. To make use of the available data, such as unit test data, functional test data, system test data, translation test data, performance test data, integration test data, and related defect data, the present invention gathers and utilizes known defect data for each discrete software application, and subsequently calculates the probability of failure for each known business transaction that uses each of these individual software applications, and then combines the transaction failure rates to predict an overall transaction failure rate in the target computer environment.

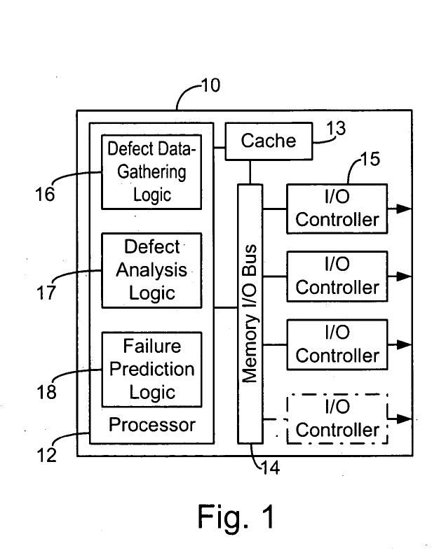

FIG. 1 is a block diagram of the system for assessing the probability of transaction success of business transaction that will interact with one or more other software applications that in a computer environment. The system includes a computer platform 10 comprised of a processor 12, cache 13, a memory bus 14, and series of input-out controllers 15. The system can be alternately embodied on computer platforms of different construction and arrangement as would be known to one of skill in the art. The processor 12 includes at least a defect data-gathering logic 16 that gathers defect data for the software applications in the target computer environment, a defect analysis logic 17 for analyzing the defect data in view of the software applications and the target computer environment, and a failure prediction logic 18 that predicts a business transaction failure rate within the target computer environment with the one or more other software applications. The logic can be implemented in software, hardware, firmware, or a combination thereof.

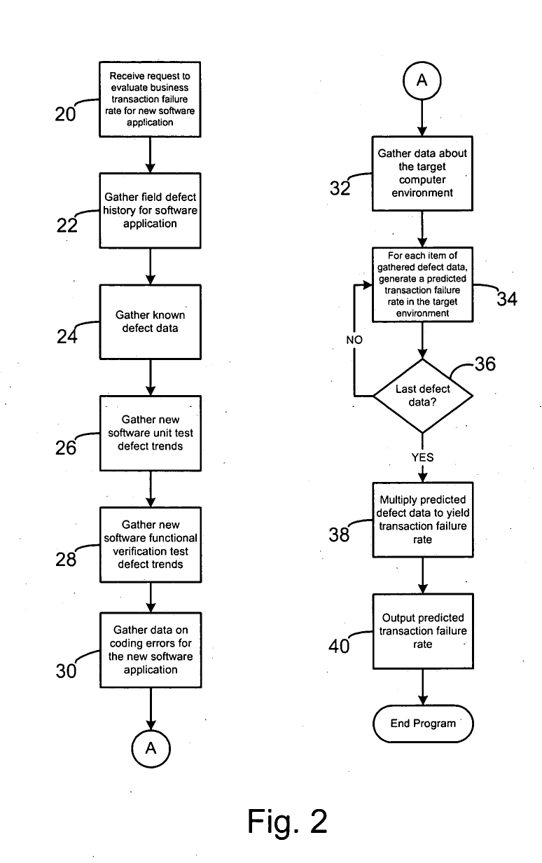

One embodiment of a process to predict the overall transaction failure rate is more particularly shown in the flowchart of FIG. 2. The computer system executing the steps of the process assesses the probability of transaction success of a first software application that will interact with one or more other software applications that in a target computer environment is shown in FIG. 2. The system receives a request to evaluate the failure rate for each individual software application, as shown at step 20, and then the data gathering of at least known defect data for the overall business transaction occurs.

In this embodiment, the system first gathers the defect history for the software application, as shown at step 22, and then the known defect data for the first software application is gathered as shown at step 24. The known defect data is any specific known defect with the software itself, with such defect affecting functionality of the software and likely adversely affecting business transactions made through the software. The specific new software unit defect trends are gathered, as shown at step 26, whereby the potential and likely defect trends that have been noted can be used in the later analysis. Then the functional verification test defect trends for the software are gathered, as shown at step 28, such information being typically produced from initial testing of the software application and the testing indicating a potential set of defect trends. The data on known specific coding errors is gathered, as shown at step 30, and the data includes such known problems as average errors per lines of codes. Other known and predictive failure data can be gathered in addition to the above, and the system can likewise gather less than the above data to make a predictive analysis as described herein.

Once all of the relevant defect data is gathered, the relevant data about the target computer environment is gathered, as shown by step 32, such that the defect data can be analyzed in view of the one or more other software applications being placed within it. Then, for each of item of the gathered defect data, i.e. each potential factor for transaction failure given the known defect, the system generated a predicted business transaction failure rate based upon that item, as shown at step 34. For example, the known unit defects may predict a failure transaction rate of f1, and the then the unit defect trends may predict a transaction failure rate of f2. The process then iterates at decision 36 wherein it is determined as to whether the last defect data item has been reached. If not, the system iterates to the next item and repeats step 34.

If the last item has been reached at decision 36, then the system multiplies the individual predicted failure rates to yield a predicted transaction failure rate (Tf) for all transactions if the new software application is placed in the target computer environment. Thus, Tf=f1×f2×f3 . . . ×fn. The predicted business transaction failure rate is then output as shown at step 40 and the process terminates.

The present invention can use any known methodology to quantify the likelihood of failure for individual applications, and preferably includes all phases of defect analysis for prior releases such as unit test data, functional test data, system test data, translation test data, performance test data, integration test data, prior release field-reported defect history, prior-release trouble ticket history, current release unit test defect trends, current release functional verification test defect trends, current software release system, performance, integration, and other test defect trends, errors per function points or lines of code modified in this release and other sources known in the art.

As a result of applying this methodology to business transaction success prediction, a significant advance and a far more realistic measure of the likelihood of success in the wide range of target potential client environments is achieved. The present methodology can be implemented in a software application that takes as input available data from the categories described above. A confidence factor can be provided for the probability of failure, and as a result, it is possible to detail a range of likely field success by transaction.

Once the transaction failure rate is predicted, the field success data can be stored in a dataset, and can be simplified into a predicted failure rate for any business transaction using the new application. In addition, the application in question will likely have varying rates of success for specific networks and operating systems, and the output of the predictive analysis can be customized to more accurately reflect the target environment's intended configuration.

It should be noted that using this methodology, the probability of success (or failure) can be customized to match the business transaction characteristics for given customers. This solution will allow a vendor to quantify the relative likelihood of success for this transaction as opposed to other possible configurations that could support the same transaction (potentially using different tools or applications), and even by the customer to analyze sophisticated vendor claims.

It can therefore be seen that the present system provides a method for assessing the probability of success for business transactions that will interact with one or more software applications in a target computer environment comprised, at least, of the steps of gathering defect data for the first software application (step 24), analyzing the defect data in view of the one or more other software applications and the target computer environment (step 34), and predicting a business transaction failure rate within the computer environment with the one or more other software applications (step 38). The method can include the step of outputting, as data, the predicted business transaction failure rate (step 40).

The present method may be implemented, for example, by operating portion(s) of a network to execute a sequence of machine-readable instructions, or device platform. The instructions can reside in various types of signal-bearing or data storage primary, secondary, or tertiary media. The media may comprise, for example, RAM accessible by, or residing within, other computer components on a processor or on a network. Whether contained in RAM, a diskette, or other secondary storage media, the instructions may be stored on a variety of machine-readable data storage media, such as DASD storage (e.g., a conventional “hard drive” or a RAID array), magnetic tape, electronic read-only memory (e.g., ROM, EPROM, or EEPROM), flash memory cards, an optical storage device (e.g. CD-ROM, WORM, DVD, digital optical tape), paper “punch” cards, or other suitable data storage media including digital and analog transmission media.

While the foregoing disclosure shows illustrative embodiments of the invention, it should be noted that various changes and modifications could be made herein without departing from the scope of the invention as defined by the appended claims. Furthermore, although elements of the invention may be described or claimed in the singular, the plural is contemplated unless limitation to the singular is explicitly stated.

1. A method for assessing the probability of transaction success of a business transaction that will interact with one or more software applications in a target computer environment, the method comprising the steps of:
gathering defect data for the software applications in the target environment;
analyzing the defect data in the target computer environment; and
predicting a transaction failure rate for the business transaction operating within the computer environment with the one or more other software applications.

2. The method of claim 1, wherein the gathered defect data includes unit test data.

3. The method of claim 1, wherein the gathered defect data includes functional test data.

4. The method of claim 1, wherein the gathered defect data includes system test data.

5. The method of claim 1, wherein the gathered defect data includes translation test data.

6. The method of claim 1, wherein the gathered defect data includes performance test data.

7. The method of claim 1, wherein the gathered defect data includes integration test data.

8. The method of claim 1, further comprising the step of outputting the predicted transaction failure rate.

9. A system for assessing the probability of business transaction success that will interact with one or more software applications in a target computer environment, the system comprising:
defect data-gathering logic for gathering defect data for the first software application defect data;
defect analysis logic for analyzing the defect data in view of the one or more software applications and the target computer environment; and
failure prediction logic for predicting a transaction failure rate for the business transaction operating within the computer environment with the one or more other software applications.

10. The system of claim 9, wherein the gathered defect data includes unit test data.

11. The system of claim 9, wherein the gathered defect data includes functional test data.

12. The system of claim 9, wherein the gathered defect data includes system test data.

13. The system of claim 9, wherein the gathered defect data includes translation test data.

14. The system of claim 9, wherein the gathered defect data includes performance test data.

15. The system of claim 9, wherein the gathered defect data includes integration test data.

16. The system of claim 9, wherein the system further outputs the predicted business transaction failure rate.

17. A system for assessing the probability of transaction success of a business transaction that will interact with one or more other software applications in a target computer environment, the system including:
a means for gathering defect data for the software applications in the target computer environment;
a means for analyzing the defect data in view of the one or more other software applications and the target computer environment; and
a means for predicting a transaction failure rate for the first software application operating within the computer environment with the one or more other software applications.
